(19) United States
(12) Patent Application Publication
(10) Pub. No.: US 2023/0402490 A1
(43) Pub. Date: Dec. 14, 2023

(54) SEMICONDUCTOR LIGHT-EMITTING DEVICE

(71) Applicant: SL ENERGY CO., LTD., Gyeonggi-do (KR)

(72) Inventors: Tae Hyun KIM, Gyeonggi-do (KR); Sung Chan LEE, Gyeonggi-do (KR)

(21) Appl. No.: 18/036,051

(22) PCT Filed: May 24, 2021
(86) PCT No.: PCT/KR2021/006396

§ 371 Date: May 9, 2023

(30) Foreign Application Priority Data
Nov. 12, 2020 (KR) 10-2020-0150841

(51) Int. Cl. H01L 27/15

(52) U.S. Cl. CPC H01L 27/156

(57) ABSTRACT

The present invention relates to a semiconductor light emitting device, and more particularly, to a light emitting device with an increased reliability in light emitting areas in the manufacture of multiple light emitting units that are electrically connected to each other. In the semiconductor light emitting device according to the present invention, at least one of the first upper electrode or the second upper electrode is configured to be electrically connected to the first pad electrode or the second pad electrode, respectively, at least partially on the upper portions of the respective light emitting units that are at least partially covered by the first pad electrode or the second pad electrode.

### FIELD

The present disclosure generally relates to a semiconductor light emitting device, and more particularly, to a light emitting device with an increased reliability in light emitting areas in the manufacture of multiple light emitting units that are electrically connected to each other.

### BACKGROUND

This section provides background information related to the present disclosure which is not necessarily prior art.

FIG. 1 shows an example of a semiconductor light emitting device disclosed in U.S. Pat. No. 7,262,436, wherein the semiconductor light emitting device comprises a substrate 100, an n-type semiconductor layer 300 grown on the substrate 100, an active layer 400 grown on the n-type semiconductor layer 300, a p-type semiconductor layer 500 grown on the active layer 400, electrodes 901, 902, 903 formed on the p-type semiconductor layer 500 to serve as reflective films, and an n-side bonding pad 800, also serving as an electrode, formed on an etched and exposed portion of the n-type semiconductor layer 300.

A chip having this configuration, i.e., with all of the electrodes 901, 902 and 903 and the electrode 800 being formed on one side of the substrate 100 and the electrodes 901, 902 and 903 functioning as reflective films, is called a flip chip. The electrodes 901, 902, 903 are comprised of the electrode 901 having high reflectivity (e.g., Ag), the electrode 903 for bonding (e.g., Au) and the electrode 902 (e.g., Ni) for preventing diffusion between a material of the electrode 901 and a material of the electrode 903. While this metal reflective film structure exhibits a high reflectance and is advantageous for current spreading, light absorption by the metal needs to be overcome.

FIG. 2 shows an example of a semiconductor light emitting device disclosed in Japanese Patent Application Publication No. 2006-120913, wherein the semiconductor light emitting device comprises a substrate 100, a buffer layer 200 grown on the substrate 100, an n-type semiconductor layer 300 grown on the buffer layer 200, an active layer 400 grown on the n-type semiconductor layer 300, a p-type semiconductor layer 500 grown on the active layer 400, a light transmitting conductive film 600 formed on the p-type semiconductor layer 500 for current spreading, a p-side bonding pad 700 formed on the light transmitting conductive film 600, and an n-side bonding pad 800 formed on an etched exposed portion of the n-type semiconductor layer 300. Further, a DBR (Distributed Bragg Reflector) 900 and a metal reflective film 904 are provided on the light transmitting conductive film 600. While this configuration reduces light absorption by the metal reflective film 904, current diffusion is relatively poor, compared to using the electrodes 901, 902, 903.

FIG. 3 shows an example of serially connected LEDs A, B disclosed in U.S. Pat. No. 6,547,249, where a plurality of LEDs is used in series connection due to various advantages. For example, by connecting the LEDs A, B in series, the number of external circuits and wire connections may be reduced, and the light absorption loss due to the wires may be lowered. Moreover, the power supply circuit can be further simplified as the total operating voltage of these serially connected LEDs A, B increases.

To connect these LEDs A, B in series, an interconnector 34 is usually deposited that connects the p-side electrode 32 and the n-side electrode 32 of neighboring LEDs A, B. However, it is not easy to form the interconnector 34 because, during the isolation process where the plurality of LEDs A, B is electrically insulated and the semiconductor layers are etched to expose a sapphire substrate 20, the etch depth is large, taking more time, and the step height is also large. An insulating layer 30 may be used to for the interconnector 34 with a gentle slope as illustrated in FIG. 3, the LEDs A, B may be spaced farther apart, which can cause problems with integration improvement.

FIG. 4 shows an example of an LED array disclosure in U.S. Pat. No. 7,417,259, where LEDs are arranged in a two-dimensional pattern on the insulating substrate for high drive voltage and low current operation. The insulating substrate used is a monolithic sapphire substrate, and two LED arrays are connected in inverse parallel on the substrate. Therefore, AC power can be used directly as the driving power.

### SUMMARY

This section provides a general summary of the disclosure and is not a comprehensive disclosure of its full scope or all of its features.

According to one aspect of the present disclosure, there is provided a semiconductor light emitting device, comprising: a first array of light emitting units 1000 comprising a first light emitting unit 101 and a second light emitting unit 102 spaced apart from each other on a substrate 10; a second array of light emitting units 2000 comprising a third light emitting unit 103 and a fourth light emitting unit 104 spaced apart from each other on the substrate 10; a first pad electrode 70a electrically connected to the first light emitting unit 101; a second pad electrode 70b electrically connected to the fourth light emitting unit 104; a first upper electrode 80a provided above and electrically connected to the first pad electrode 70a; and a second upper electrode 80b provided above and electrically connected to the second pad electrode 70b, wherein each of the first to fourth light emitting units 101, 102, 103, 104 includes a first semiconductor layer 30 having a first conductivity, a second semiconductor layer 50 having a second conductivity different from the first conductivity, and an active layer 40 interposed between the first semiconductor layer 30 and the second semiconductor layer 50 for generating light by recombination of electrons and holes, and wherein the first to fourth light emitting units 101, 102, 103, 104 are electrically connected to one another, and the first pad electrode 70a is arranged to cover both the first and second light emitting units 101, 102.

### BRIEF DESCRIPTION OF THE DRAWINGS

Various objects, features and attendant advantages of the present invention will become fully appreciated when considered in conjunction with the accompanying drawings, in which like reference characters designate the same or similar parts throughout the several views, and wherein:

FIG. 1 shows an example of a semiconductor light emitting device disclosed in U.S. Pat. No. 7,262,436.

FIG. 2 shows an example of a semiconductor light emitting device disclosed in Japanese Patent Application Publication No. 2006-120913.

FIG. 3 shows an example of serially connected LEDs A, B disclosed in U.S. Pat. No. 6,547,249.

FIG. 4 shows an example of an LED array disclosure in U.S. Pat. No. 7,417,259.

FIG. 5 shows a three-dimensional schematic view of a semiconductor light emitting device according to one embodiment of the present invention.

FIG. 6 shows a schematic side view of a semiconductor light emitting device according to one embodiment of the present invention.

FIG. 7 shows a schematic top view of a semiconductor light emitting device according to one embodiment of the present invention.

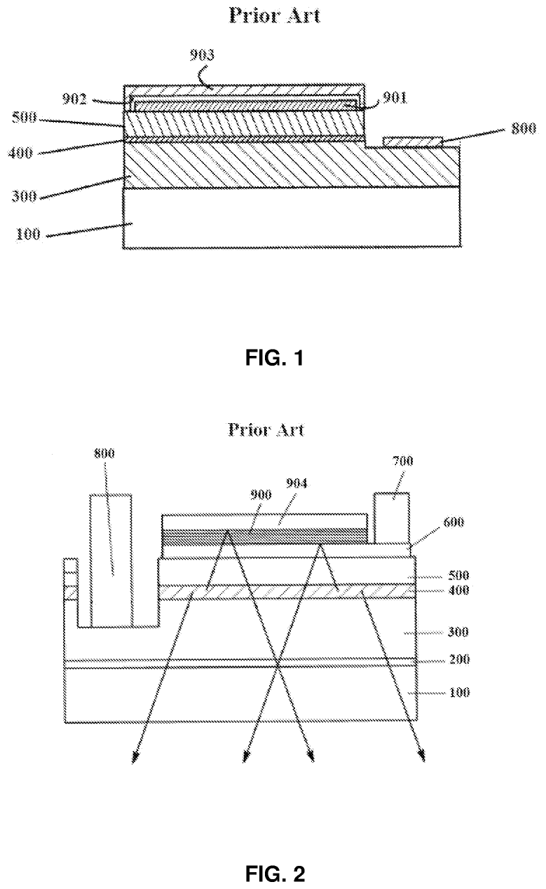

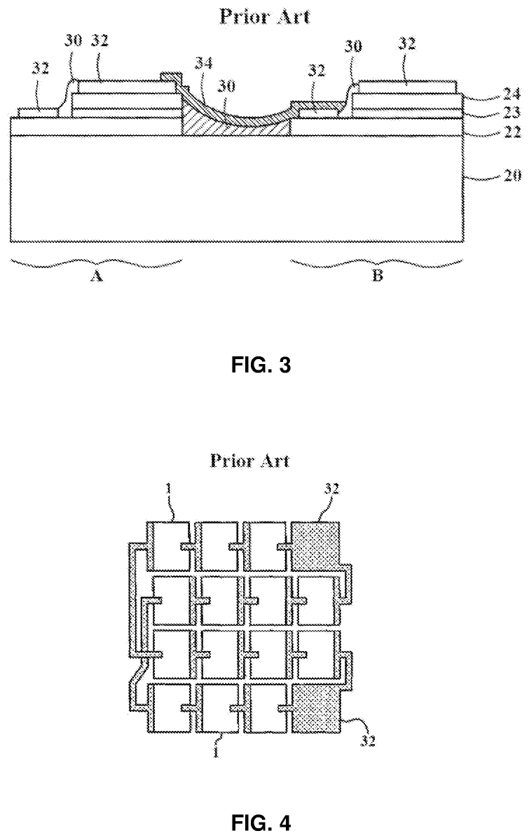

### DETAILED DESCRIPTION

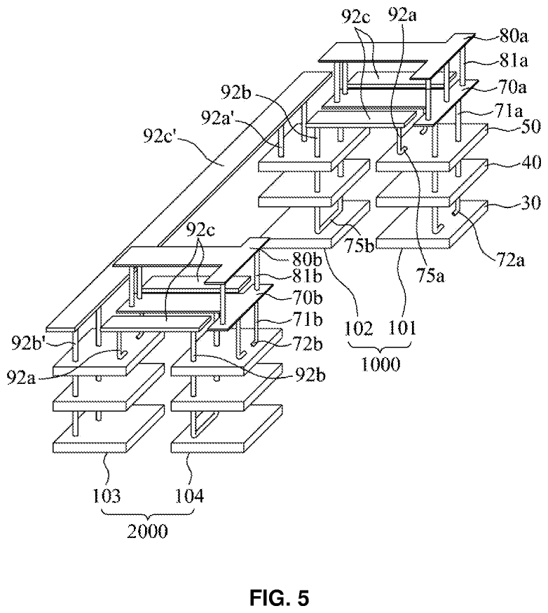

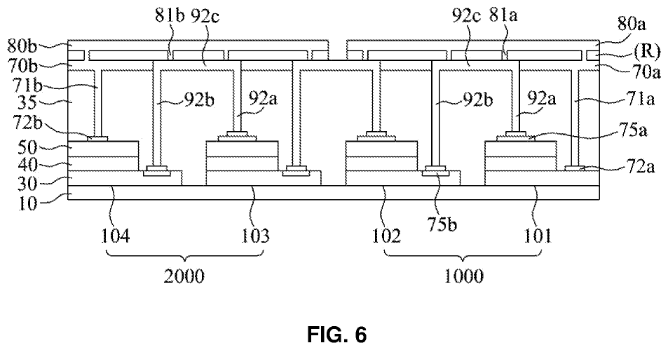

FIG. 5 shows a three-dimensional schematic view of a semiconductor light emitting device according to one embodiment of the present invention, and FIG. 6 shows a schematic side view of a semiconductor light emitting device according to one embodiment of the present invention.

Referring to FIGS. 5 and 6, the semiconductor light emitting device may include a first array of light emitting units 1000 comprising a first light emitting unit 101 and a second light emitting unit 102 spaced apart from each other on a substrate 10, a second array of light emitting units 2000 comprising a third light emitting unit 103 and a fourth light emitting unit 104 spaced apart from each other on the substrate 10, a first pad electrode 70a electrically connected to the first light emitting unit 101, a second pad electrode 70b electrically connected to the fourth light emitting unit 104, a first upper electrode 80a provided above and electrically connected to the first pad electrode 70a, and a second upper electrode 80b provided above and electrically connected to the second pad electrode 70b. Here, each of the first to fourth light emitting units 101, 102, 103, 104 includes a first semiconductor layer 30 having a first conductivity, a second semiconductor layer 50 having a second conductivity different from the first conductivity, and an active layer 40 interposed between the first semiconductor layer 30 and the second semiconductor layer 50 for generating light by recombination of electrons and holes. The first to fourth light emitting units 101, 102, 103, 104 are electrically connected to one another, and the first pad electrode 70a may be arranged to cover both the first and second light emitting units 101, 102.

The semiconductor light emitting device according to one embodiment of the present invention may comprise a first array of light emitting units 1000 including a first light emitting unit 101 and a second light emitting unit 102 spaced apart from each other on the substrate; and a second array of light emitting units 2000 including a third light emitting unit 103 and a fourth light emitting unit 104 spaced apart from each other on the substrate.

The first to fourth light emitting units 101, 102, 103, 104 may be electrically connected to one another.

Each of the first to fourth light emitting units 101, 102, 103, 104 may have a plurality of semiconductor layers, comprising: a first semiconductor layer 30 having a first conductivity, a second semiconductor layer 50 having a second conductivity different from the first conductivity, and an active layer 40 interposed between the first semiconductor layer 30 and the second semiconductor layer 50 for generating light by recombination of electrons and holes.

The substrate 10 may be made of sapphire, SiC, Si, GaN or the like, which is eventually removed.

The plurality of semiconductor layers may be comprised of a buffer layer (not shown) formed on the substrate 10, the first semiconductor layer 30 having a first conductivity (e.g. a Si-doped GaN layer), the second semiconductor layer 50 having a second conductivity different from the first conductivity (e.g. a Mg-doped GaN layer), and the active layer 40 interposed between the first semiconductor layer 30 and the second semiconductor layer 50 for generating light by recombination of electrons and holes (e.g. an InGaN/(In)/GaN layer with the multiple quantum well (MQW) structure). Each semiconductor layer may be formed of a multi-layered structure, and the buffer layer may be omitted. The positions of the first and second semiconductor layers 30, 50 can be swapped. Additionally, the first and second semiconductor layers 30, 50 may be made of GaN in the case of Group 3 nitride semiconductor light emitting devices.

The semiconductor light emitting device according to one embodiment of the present invention may comprise the first pad electrode 70a electrically connected to the first light emitting unit 101, and the second pad electrode 70b electrically connected to the fourth light emitting unit 104, as shown in FIGS. 5 and 6.

To elaborate on this by referring back to FIGS. 5 and 6, the first pad electrode 70a may be in electrical communication with the first semiconductor layer 30 of the first light emitting unit 101 by a first electrical connection 71a that passes through the second semiconductor layer 50 and the active layer 40, among the plurality of semiconductor layers. Likewise, the second pad electrode 70b may be in electrical communication with the second semiconductor layer 50 of the fourth light emitting unit 104 by a second electrical connection 71b.

As will be describe later, when an insulating layer 35 is provided between the plurality of light emitting units, the first electrical connection 71a and the second electrical connection 71b pass through the insulating layer 35 to be in electrical communication with the first semiconductor layer 30 of the first light emitting unit 101 and the second semiconductor layer 50 of the fourth light emitting unit 104, respectively,

That is, the first pad electrode 70a and the second pad electrode 70b may be in electrical communication with the first semiconductor layer 30 of the first light emitting unit 101 and the second semiconductor layer 50 of the fourth light emitting unit 104 by the first electrical connection 71a and the second electrical connection 71b, respectively, that pass through the insulating layer 35 (to be described below).

In another embodiment of the present invention, the first pad electrode 70a may be disposed to cover both the first light emitting part 101 and the second light emitting part 102. Similarly, the second pad electrode 70b may be disposed to cover both the third light emitting part 103 and the fourth light emitting part 104.

This configuration of the pad electrode 70 mitigates impacts or scratches between the chip surface and the multi-layers that can occur during the die bonding process. In this way, potential defects that may occur in the process of manufacturing can be monitored and prevented. Moreover, it is possible to improve the reliability by reducing weak/non-lighting in some of the light emitting areas that are observed in the HV (High-Voltage) chip structure.

As mentioned earlier, the semiconductor light emitting device according to the present invention may include the first upper electrode 80a provided above and electrically connected to the first pad electrode 70a, and the second upper electrode 80b provided above and electrically connected to the second pad electrode 70b.

To elaborate on this by referring again to FIGS. 5 and 6, the first upper electrode 80a is disposed above the first pad electrode 70a and electrically connected to the first pad electrode 70a. That is, the first upper electrode 80a can be arranged such that it can cover the first pad electrode 70a. Likewise, the second upper electrode 80b is disposed above the second pad electrode 70b and electrically connected to the second pad electrode 70b. That is, the second upper electrode 80b can be arranged such that it can cover the second pad electrode 70b.

In another embodiment, the first upper electrode 80a may be disposed on the first pad electrode 70a, above the first and second light emitting units 101, 102. Likewise, the second upper electrode 80b may be disposed on the second pad electrode 70b, above the third and fourth light emitting units 103, 104.

In another embodiment, the electrode connection 81 formed above each of the first and second light emitting units 101, 102 serves to electrically connect the first upper electrode 80a and the first pad electrode 70a. Likewise, the electrode connection 81 formed above each of the third and fourth light emitting units 103, 104 serves to electrically connect the second upper electrode 80b and the second pad electrode 70b.

To elaborate on this by referring again to FIGS. 5 and 6, in the upper portions of the respective first and second light emitting units 101, 102, the first pad electrode 70a is arranged to cover both the first light emitting unit 101 and the second light emitting unit 102, and the first upper electrode 80a disposed above the first pad electrode 70a is configured to be electrically connected to the first pad electrode 70a. As illustrated in FIGS. 5 and 6, above each of the first and second light emitting units 101, 102, the first upper electrode 80a and the first pad electrode 70a are electrically connected to each other by the first electrode connection 81a.

Likewise, in the upper portions of the third and fourth light emitting units 103, 104, the second pad electrode 70b is arranged to cover both the third light emitting unit 103 and the fourth light emitting unit 104, and the second upper electrode 80b disposed above the second pad electrode 70b is configured to be electrically connected to the second pad electrode 70b. As illustrated in FIGS. 5 and 6, above each of the third and fourth light emitting units 103, 104, the second upper electrode 80b and the second pad electrode 70b are electrically connected to each other by the second electrode connection 81b.

The semiconductor light emitting device of the present invention may further include a first connecting electrode 92 for electrically connecting the first light emitting unit 101 and the second light emitting unit 102. This first connecting electrode 92 also electrically connects the third light emitting unit 103 and the fourth light emitting unit 104.

Referring again to FIGS. 5 and 6, the first connecting electrode 92 includes a first lower connection 92a, a first horizontal connection 92c, and a second lower connection 92b.

The first horizontal connection 92c is positioned across the upper portions of the respective first and second light emitting unit 101, 102. The first lower connection 92a electrically connects one end of the first horizontal connection 92c to the second semiconductor layer 50 of the first light emitting unit 101. The second lower connection 92b electrically connects the other end of the first horizontal connection 92c to the first semiconductor layer 30 of the second light emitting unit 102.

When the insulating layer 35 is provided between the first light emitting unit 101 and the second light emitting unit 102, the first lower connection 92a and the second lower connection 92b may pass through the insulating layer 35 to be in electrical communication with the second semiconductor layer 50 of the first light emitting unit 101 and with the first semiconductor layer 30 of the second light emitting unit 102, respectively.

In another embodiment, the first horizontal connection 92c can be formed on a layer at the same height as the first pad electrode 70a.

In a further embodiment of the semiconductor light emitting device, the first pad electrode 70a is positioned across a central region in the upper portions of the respective first and second light emitting units 101, 102 to cover both the first light emitting unit 101 and the second light emitting unit 102, and the first horizontal connection 92c may be positioned at a distance from the first pad electrode 70a, along the left and/or right edges in the upper portions of the respective first and second light emitting units 101, 102.

To elaborate on this by referring back to FIGS. 5 and 6, the first pad electrode is positioned across a central region in the upper portions of the respective first and second light emitting units 101, 102, such that it may cover both the first light emitting unit 101 and the second light emitting unit 102. In this case, the first horizontal connection 92c is spaced from the first pad electrode 70a by a certain distance, along the left and/or right edges in the upper portions of the respective first and second light emitting units 101, 102 (i.e., along the shorter sides), and electrically connects the first light emitting unit 101 and the second light emitting unit 102.

Likewise, the second pad electrode 70b is positioned across a central region in the upper portions of the third and fourth light emitting units 103, 104, such that it may cover both the third light emitting unit 103 and the fourth light emitting unit 104. In this case, the first horizontal connection 92c is spaced from the second pad electrode 70b by a certain distance, along the left and/or right edges in the upper portions of the third light emitting unit 103 and the fourth light emitting unit 104 (i.e., along the shorter sides), and electrically connects the third light emitting unit 103 and the fourth light emitting unit 104.

Additionally, the first horizontal connection 92c of the first connecting electrode 92 may be formed on a layer at the same height as the pad electrode 70. Thus, when the pad electrode 70 is disposed to cover both the first light emitting unit 101 and the second light emitting unit 102, the first horizontal connection 92c of the first connecting electrode 92 may be formed on a layer at the same height as the pad electrode 70 to electrically connect the first light emitting unit 101 and the second light emitting unit 102. While the first horizontal connection 92c of the first connecting electrode 92 is formed on a layer at the same height as the pad electrode 70, they are both electrically insulated from each other, i.e., they are arranged not to be overlapped with each other.

In another embodiment of the semiconductor light emitting device, a first branched finger electrode 75a may be formed on the second semiconductor layer 50 of the first light emitting unit 101, in the horizontal direction relative to the second semiconductor layer 50. Likewise, a second branched finger electrode 75b may be formed on the first semiconductor layer 30 of the second light emitting unit 102, in the horizontal direction relative to the first semiconductor layer 30.

In a preferred embodiment, the first branched finger electrode 75a and/or the second branched finger electrode 75b may be arranged such that they are covered by the first pad electrode 70a and the first upper electrode 80a.

As illustrated in FIGS. 5 and 6, the first branched finger electrode 75a may be formed on the second semiconductor layer 50, extending outwards from the bottom of the first lower connection 92a, and the second branched finger electrode 75b may be formed on the first semiconductor layer 30, extending outwards from the bottom of the second lower connection 92b.

In a preferred embodiment, when the first horizontal connection 92c of the first connecting electrode 92 is formed along the left and/or right edges of the respective light emitting units (i.e., along the shorter sides), the second branched finger electrode 75b may be formed such that it interconnects between the second lower connections 92b of the first connecting electrodes 92 formed along the left and/or right edges of the respective light emitting units.

Another embodiment of the semiconductor light emitting device may further include a second connecting electrode 92′ for connecting the second light emitting unit 102 and the third light emitting unit 103. This second connecting electrode 92′ may include a first-a lower connection 92a′, a second horizontal connection 92c′ and a second-a lower connection 92b′.

The second horizontal connection 92c′ is positioned across the upper portions of the second light emitting unit 102 and the third light emitting unit 103. The first-a lower connection 92a′ electrically connects one end of the second horizontal connection 92c′ to the second semiconductor layer 50 of the second light emitting unit 102. The second-a lower connection 92b′ electrically connects the other end of the second horizontal connection 92c′ to the first semiconductor layer 30 of the third light emitting unit 103.

The second horizontal connection 92c′ may be formed on a layer at the same height as the first pad electrode 70a, on an upper portion of the second light emitting unit 102 that is not covered by the first pad electrode 70a.

Further, the second horizontal connection 92c′ may be formed on a layer at the same height as the second pad electrode 70b, on an upper portion of the third light emitting unit 103 that is not covered by the second pad electrode 70b.

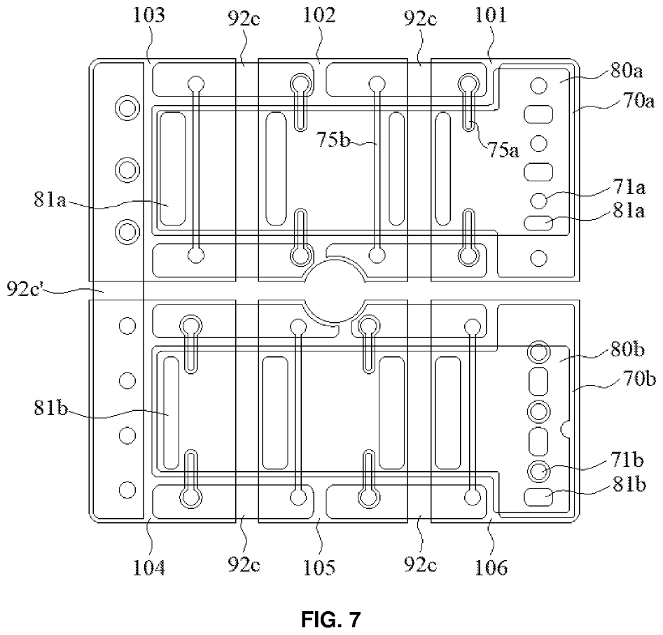

FIG. 7 shows a schematic top view of a semiconductor light emitting device according to one embodiment of the present invention.

Referring to FIG. 7, the semiconductor light emitting device may include a first array of light emitting units comprising a first light emitting unit 101, a second light emitting unit 102 and a third light emitting unit 103 that are spaced apart from one another on the substrate, a second array of light emitting units comprising a fourth light emitting unit 104, a fifth light emitting unit 105 and a sixth light emitting unit 106 that are spaced apart from each other on the substrate, a first pad electrode 70a electrically connected to the first light emitting unit 101, a second pad electrode 70b electrically connected to the sixth light emitting unit 106, a first upper electrode 80a provided above and electrically connected to the first pad electrode 70a, and a second upper electrode 80b provided above and electrically connected to the second pad electrode 70b.

Other components of the semiconductor light emitting device in FIG. 7 have similar functions and features as described above with reference to FIGS. 5 and 6, except that a second connecting electrode 92′ for connecting the third light emitting unit 103 and the fourth light emitting unit 104 is additionally included. The second connecting electrode 92′ may include a first-a lower connection 92a′, a second horizontal connection 92c′, and a second-a lower connection 92b′. The lower connections are not shown in FIG. 7.

The second horizontal connection 92c′ is positioned across the upper portions of the third and fourth light emitting units 103, 104. The first-a lower connection 92a′ electrically connects one end of the second horizontal connection 92c′ to the second semiconductor layer 50 of the third light emitting unit 103. The second-a lower connection 92b′ electrically connects the other end of the second horizontal connection 92c′ to the first semiconductor layer 30 of the fourth light emitting unit 104.

The second horizontal connection 92c′ may be formed on a layer at the same height as the first pad electrode 70a, on an upper portion of the third light emitting unit 103 that is not covered by the first pad electrode 70a.

Further, the second horizontal connection 92c′ may be formed on a layer at the same height as the second pad electrode 70b, on an upper portion of the fourth light emitting unit 104 that is not covered by the second pad electrode 70b.

The following will now describe a method for manufacturing a semiconductor light emitting device (for example, a Group III nitride semiconductor light emitting device) according to one embodiment of the present invention.

First, a plurality of semiconductor layers 30, 40, 50 is formed on a substrate 10, and individual light emitting units are isolated by mesa etching, for example. In this embodiment, the semiconductor light emitting device comprises a first to a fourth light emitting unit 101, 102, 103, 104. Additionally, or alternatively, the number of light emitting units can vary. For example, three or at least five light emitting units can be provided.

In each light emitting unit, a trench is formed by removing the surrounding area of the plurality of semiconductor layers 30, 40, 50. Thus, each light emitting unit itself is electrically isolated or insulated from each other. In this embodiment, each light emitting unit may have a substantially rectangular shape when viewed from above, so that one side (which is often referred to as the length) faces its opposite side. One pair of opposite sides are longer (i.e., longer sides) than the other pair (i.e., shorter sides).

Next, an insulating layer 35 is formed between the plurality of light emitting units. The insulating layer 35 in this embodiment may be formed under the first horizontal connection 92c of the first connecting electrode 92. The insulating layer 35 is a passivation layer having light-transmitting properties that is made of a material such as SiO₂, TiO₂, Al₂O₃ or the like, preferably in-between the entire light emitting units facing each other. In the case of a semiconductor light emitting device operating at a high voltage, if the space between the neighboring light emitting units is narrow, it is advantageous to form the insulating layer 35 for electrical insulation as in this embodiment, by connecting the plurality of light emitting devices in series. Additionally, as the insulating layer 35 extends to an exposed portion of the substrate 10 at the edges of the light emitting units, it may further enhance the reliability of electrical insulation and may help to alleviate or even out any unevenness (e.g. step) or height differences when forming the insulating reflective layer R (to be described later).

A branched finger electrode 75 and an ohmic electrode 72, which will be described later, may be formed over the second semiconductor layer 50. Also, it is desirable to have a light absorption barrier under the electrodes to reflect light or to prevent the current from flowing directly below the electrodes. In this embodiment, the insulating layer 35 can also serve as a light absorption barrier as it is extended.

Once the insulating layer 35 is formed, a current spreading conductive layer can be formed on top of the second semiconductor layer 50. When this p-type second semiconductor layer 50 is made of GaN, the current spreading conductive layer can be very helpful as P-type GaN is known to have a poor current spreading ability. Exemplary materials for the current spreading conductive layer include ITO, Ni/Au or the like.

To continue, the first connecting electrode 92, the branched finger electrode 75 and the ohmic electrode 72 are formed.

The first connecting electrode 92 in each of the light emitting units is formed using the same process. The first connecting electrode 92 for connecting the first light emitting unit 101 and the second light emitting unit 102 includes, for example, a first lower connection 92a, a first horizontal connection 92c, and a second lower connection 92b.

The insulating layer 35 has an opening in which the first lower connection 92a is formed. The second lower connection 92b is formed in another opening present in the insulating layer 35, the second semiconductor layer 50 and the active layer 40. The first horizontal connection 92c is formed on the insulating layer 35 such that it covers the upper portions of the respective first and second light emitting units 101, 102. As such, the first lower connection 92a is configured to pass through the insulating layer 35 to electrically connect the first horizontal connection 92c to the first semiconductor layer 30 of the first light emitting unit 101, while the second lower connection 92b is configured to pass through the insulating layer 35, the second semiconductor layer 50 and the active layer to electrically connect the first horizontal connection 92c to the second semiconductor layer 50 of the second light emitting unit 102. Moreover, the first horizontal connection 92c of the first connecting electrode 92 may be formed on a layer at the same height as a layer on which the pad electrode 70 is formed (to be described later).

In particular, the first horizontal connection 92c of the first connecting electrode 92 may be formed on a layer at the same height as the first pad electrode 70a (to be described later), along the left and/or right edges (i.e., along the shorter sides) of each of the first and second light emitting units 101, 102 in the longitudinal direction where the first light emitting unit 101 and the second light emitting unit 102 are connected, thereby electrically connecting the first light emitting unit 101 and the second light emitting unit 102.

Referring back to FIG. 5, the second light emitting unit 102 and the third light emitting unit 103 may be electrically connected by a second connecting electrode 92′. The second horizontal connection 92c′ of the second connecting electrode 92′ that electrically connects the second light emitting unit 102 and the third light emitting unit 103 may be formed on a layer at the same height as the first pad electrode 70a and the second pad electrode 70b, along the longer sides of each of the second and third light emitting units 102, 103 that are not covered by the first and second pad electrodes 70a, 70b.

Additionally, the branched finger electrode 75 is formed at the bottom of each of the first and second lower connections 92a, 92b of the first connecting electrode 92. In particular, in the case of the first light emitting unit 101 and the second light emitting unit 102, for example, a first branched finger electrode 72a is formed at the bottom of the first lower connection 92a and over the second semiconductor layer 50. Likewise, a second branched finger electrode 75b is formed at the bottom of the second lower connection 92b and over the first semiconductor layer 30.

In another embodiment, the first horizontal connection 92c of the first connecting electrode 92 is formed along the left and/or right edges (i.e., along the shorter sides) of each of the light emitting units, and in this case the second branched finger electrode 75b is formed such that it interconnects between the second lower connections 92b of the first connecting electrodes 92 formed along the left and/or right edges of the respective light emitting units.

In another embodiment, the first and second branched finger electrodes 75a, are formed such that they are partly covered by a pad electrode 70 and an upper electrode (to be described later). In a preferred embodiment, the first and second branched finger electrodes 75a, 75b may be arranged vertically below the pad electrode and the upper electrode 80.

The pad electrode 70 is formed on a layer at the same height as the first horizontal connection 92c of the first connecting electrode 92. A first electrical connection 71a is provided into an opening that is formed in the insulating layer 35, second semiconductor layer 50 and active layer 40 of the first light emitting unit 101. A second electrical connection 71b is provided into an opening that is formed in the insulating layer of the fourth light emitting unit 104. As such, the first pad electrode 70a can be in electrical communication with the first semiconductor layer 30 of the first light emitting unit 101, by the first electrical connection 71a that passes through the insulating layer 35, second semiconductor layer 50 and active layer 40 of the first light emitting unit 101. Likewise, the second pad electrode 70b can be in electrical communication with the second semiconductor layer 50 of the fourth light emitting unit 104, by the second electrical connection 71b that passes through the insulating layer 35 of the second pad electrode 70b.

The ohmic electrode 72 is formed on the upper portions of the respective first and second semiconductor layers 30, 50, and the first electrical connection 71a and the second electrical connection 71b are each connected to this ohmic electrode 72. Optionally, the ohmic electrode 72 may be omitted but is preferably provided to reduce contact resistance and to ensure the stability of electrical connection.

The first pad electrode 70a is arranged to cover both the first light emitting unit 101 and the second light emitting unit 102 that are electrically connected to each other. The second pad electrode 70b is arranged to cover both the third light emitting unit 103 and the fourth light emitting unit 104 that are electrically connected to each other.

The first horizontal connection 92c of the first connecting electrode 92 and the pad electrode 70 are electrically insulated from each other on the layers of the same height, and they are arranged not to overlap each other.

In addition, the first pad electrode 70a is positioned across a central region of the upper portions of the respective first and second light emitting units 101, 102, such that it may cover both the first light emitting unit 101 and the second light emitting unit 102. Here, the first horizontal connection 92c of the first connecting electrode 92 is formed along the left and/or right edges (i.e., along the shorter sides) of each of the first light emitting unit 101 and the second light emitting unit 102, in the longitudinal direction where the first light emitting unit 101 and the second light emitting unit 102 are electrically connected. Also, the first horizontal connection 92c of the first connecting electrode 92 is formed on a layer at the same height as the first pad electrode 70a, thereby electrically connecting the first light emitting unit 101 and the second light emitting unit 102. Likewise, the second pad electrode 70b is positioned across a central region of the upper portions of the third and fourth light emitting units 103, 104, along the left and/or right edges (i.e., along the shorter sides) of each of the third light emitting unit 103 and the fourth light emitting unit 104, in the longitudinal direction where the third light emitting unit 103 and the fourth light emitting unit 104 are electrically connected. Also, the second pad electrode is formed on a layer at the same height as the second pad electrode 70b, thereby electrically connecting the third light emitting unit 103 and the fourth light emitting unit 104.

An insulating reflective layer R is then formed to cover the plurality of semiconductor light emitting units, the insulating layer 35, the first horizontal connection 92c of the first connecting electrode 92, and the pad electrode 70.

The insulating reflective layer R reflects light from the active layer 40 towards the substrate 10. In this embodiment, the insulating reflective layer R is made of an insulating material to reduce light absorption by the metal reflective film. Additionally, or optionally, the insulating reflective layer R may be a single layer, but it preferably has a structure of multilayers sequentially stacked, including a DBR (Distributed Bragg Reflector) or ODR (Omni-Directional Reflector). For example, the insulating reflective layer R may include a dielectric layer, a DBR layer, and a clad layer,

It should be more cautious when forming the insulating reflective layer R due to possible structural features such as height differences present in the structures below the insulating reflective layer R, for example, height differences between the plurality of light emitting units and its surrounding area, or uneven structures due to the first connecting electrode 92, the branched finger electrode 75 and the ohmic electrode 72. For example, when the insulating reflective layer R is a multi-layered structure including the DBR, each material layer should have a specially designed thickness for the insulating reflective layer R to function well. In one example, the DBR may be composed of repeatedly stacked layers of SiO₂/TiO₂, SiO₂/Ta₂O₂, or SiO₂/HfO. The SiO₂/TiO₂ layers provide good reflection efficiency for blue light, while the SiO₂/Ta₂O₂ or SiO₂/HfO layers provide good reflection efficiency for UV light. The DBR is preferably obtained by PVD (Physical Vapor Deposition), in particular, E-Beam Evaporation, sputtering, or thermal evaporation. Before depositing the DBR, which requires high precision, forming a dielectric layer of a certain thickness can help stabilize the manufacturing process of the DBR and improve light reflection. A suitable material for the dielectric layer may be SiO₂, with a thickness ranging from 0.2 μm to 1.0 μm. The clad layer may be made of Al₂O₃, SiO₂, SiON, MgF, CaF, or the like. For example, the total thickness of the insulating reflective layer R may range from 1 μm to 8 μm, for example.

Subsequently, an opening is formed in the insulating reflective layer R, an electrode connection is formed in the opening, and a first upper electrode 80a and a second upper electrode 80b are formed on the insulating reflective layer R.

The first upper electrode 80a and the second upper electrode 80b are arranged to cover the first pad electrode 70a and the second pad electrode 70b, respectively. Also, the first upper electrode 80a and the second upper electrode 80b are connected to the first pad electrode 70a and the second pad electrode 70b by a first electrode connection 81a and a second electrode connection 81b, respectively. The first upper electrode 80a and the second upper electrode 80b are positioned only on top of the first pad electrode 70a and the second pad electrode 70b, respectively.

Furthermore, the first pad electrode 70a is arranged to cover both the first light emitting unit 101 and the second light emitting unit 102. In this case, the first upper electrode 80a is formed to be electrically connected to the first pad electrode 70a by the first electrode connection 81a, in the upper portions of the respective first and second light emitting units 101, 102, respectively. In other words, a plurality of openings is formed in the insulating reflective layer R present in the upper portions of the respective first and second light emitting units 101, 102, the first electrode connection 81a is formed in each opening, and the first upper electrode 80a is formed on the insulating reflective layer R.

Likewise, the second pad electrode 70b is arranged to cover both the third light emitting unit 103 and the fourth light emitting unit 104. In this case, the second upper electrode 80b is formed to be electrically connected to the second pad electrode 70b by the second electrode connection 81b, in the upper portions of the third and fourth light emitting units 103, 104, respectively. In other words, a plurality of openings is formed in the insulating reflective layer R present in the upper portions of the respective third and fourth light emitting units 103, 104, the second electrode connection 81b is formed in each opening, and the second upper electrode 80b is formed on the insulating reflective layer R.

The electrode connection and the upper electrode can be formed together in the same process.

In this embodiment, the semiconductor light emitting device is a flip chip, in which the upper electrode is provided on the opposite side of the plurality of serially semiconductor layers 30, 40, 50 with respect to the insulating reflective layer R, and a plurality of light emitting units is serially connected.

As used herein, including in the claims, singular forms of terms are to be construed as also including the plural form and vice versa, unless the context indicates otherwise. Thus, it should be noted that as used herein, the singular forms “a,” “an,” and “the” include plural references unless the context clearly dictates otherwise.

Throughout the description and claims, the terms “comprise”, “including”, “having”, and “contain” and their variations should be understood as meaning “including but not limited to” and are not intended to exclude other components unless specifically so stated.

It will be appreciated that variations to the embodiments of the invention can be made while still falling within the scope of the invention. Alternative features serving the same, equivalent or similar purpose can replace features disclosed in the specification, unless stated otherwise. Thus, unless stated otherwise, each feature disclosed represents one example of a generic series of equivalent or similar features.

While the invention has been described in connection with what is presently considered to be the most practical and preferred embodiments, it is to be understood that the invention is not to be limited to the disclosed embodiment, but on the contrary, is intended to cover various modifications and equivalent arrangements included within the spirit and scope of the appended claims.

Set out below are clauses that describe diverse features of further aspects of the present disclosure.
(1) A semiconductor light emitting device, comprising: a first array of light emitting units comprising a first light emitting unit and a second light emitting unit spaced apart from each other on a substrate; a second array of light emitting units comprising a third light emitting unit and a fourth light emitting unit spaced apart from each other on the substrate; a first pad electrode electrically connected to the first light emitting unit; a second pad electrode electrically connected to the fourth light emitting unit; a first upper electrode provided above and electrically connected to the first pad electrode; and a second upper electrode provided above and electrically connected to the second pad electrode, wherein, each of the first to fourth light emitting units includes a first semiconductor layer having a first conductivity, a second semiconductor layer having a second conductivity different from the first conductivity, and an active layer interposed between the first semiconductor layer and the second semiconductor layer for generating light by recombination of electrons and holes, the first to fourth light emitting units are electrically connected to one another, and the first pad electrode is arranged to cover both the first and second light emitting units.
(2) There is also provided, the semiconductor light emitting device of clause (1), wherein the first upper electrode is disposed above the first pad electrode in the upper portions of the respective first and second light emitting units.
(3) There is also provided, the semiconductor light emitting device of clause (2), wherein the first upper electrode and the first pad electrode are electrically connected by an electrode connection formed in the upper portion of each of the first and second light emitting units.
(4) There is also provided, the semiconductor light emitting device of clause (1) or clause (2), further comprising: a first connecting electrode for electrically connecting the first light emitting unit and the second light emitting unit, wherein the first connecting electrode includes a first lower connection, a first horizontal connection, and a second lower connection, the first horizontal connection is positioned across the upper portions of the respective first and second light emitting units, the first lower connection electrically connects one end of the first horizontal connection to the second semiconductor layer of the first light emitting unit, and the second lower connection electrically connects the other end of the first horizontal connection to the first semiconductor layer of the second light emitting unit.
(5) There is also provided, the semiconductor light emitting device of clause 4, wherein the first horizontal connection and the first pad electrode are formed on layers having the same height.
(6) There is also provided, the semiconductor light emitting device of clause (4), wherein the first pad electrode is positioned across a central region in the upper portions of the respective first and second light emitting units to cover both the first light emitting unit and the second light emitting unit, and the first horizontal connection is positioned at a distance from the first pad electrode, along the left and/or right edges in the upper portions of the respective first and second light emitting units.
(7) There is also provided, the semiconductor light emitting device of clause (4), further comprising: a first branched finger electrode formed in the horizontal direction on the second semiconductor layer of the first light emitting unit, and/or a second branched finger electrode formed in the horizontal direction on the first semiconductor layer of the second light emitting unit, wherein the first branched finger electrode and/or the second branched finger electrode is arranged to be covered by the first pad electrode and the first upper electrode.
(8) There is also provided, the semiconductor light emitting device of clause (4), further comprising: a second connecting electrode for connecting the second light emitting unit and the third light emitting unit, wherein the second connecting electrode includes a first-a lower connection, a second horizontal connection, and a second-a lower connection, the second horizontal connection is positioned across the upper portions of the respective second and third light emitting units, the first-a lower connection electrically connects one end of the second horizontal connection to the second semiconductor layer of the second light emitting unit, the second-a lower connection electrically connects the other end of the second horizontal connection to the first semiconductor layer of the third light emitting unit, and the second horizontal connection is formed on a layer at the same height as the first pad electrode, in an upper portion of the second light emitting unit that is not covered by the first pad electrode.

1. A semiconductor light emitting device, comprising:
a first array of light emitting units comprising a first light emitting unit and a second light emitting unit spaced apart from each other on a substrate;
a second array of light emitting units comprising a third light emitting unit and a fourth light emitting unit spaced apart from each other on the substrate;
a first pad electrode electrically connected to the first light emitting unit;
a second pad electrode electrically connected to the fourth light emitting unit;
a first upper electrode provided above and electrically connected to the first pad electrode; and
a second upper electrode provided above and electrically connected to the second pad electrode,
wherein, each of the first to fourth light emitting units includes a first semiconductor layer having a first conductivity, a second semiconductor layer having a second conductivity different from the first conductivity, and an active layer interposed between the first semiconductor layer and the second semiconductor layer for generating light by recombination of electrons and holes,
the first to fourth light emitting units are electrically connected to one another, and
the first pad electrode is arranged to cover both the first and second light emitting units.

2. The semiconductor light emitting device of claim 1, wherein the first upper electrode is disposed above the first pad electrode in the upper portions of the respective first and second light emitting units.

3. The semiconductor light emitting device of claim 2, wherein the first upper electrode and the first pad electrode are electrically connected by an electrode connection formed in the upper portion of each of the first and second light emitting units.

4. The semiconductor light emitting device of claim 1, further comprising:
a first connecting electrode for electrically connecting the first light emitting unit and the second light emitting unit,
wherein the first connecting electrode includes a first lower connection, a first horizontal connection, and a second lower connection,
the first horizontal connection is positioned across the upper portions of the respective first and second light emitting units,
the first lower connection electrically connects one end of the first horizontal connection to the second semiconductor layer of the first light emitting unit, and
the second lower connection electrically connects the other end of the first horizontal connection to the first semiconductor layer of the second light emitting unit.

5. The semiconductor light emitting device of claim 4, wherein the first horizontal connection and the first pad electrode are formed on layers having the same height.

6. The semiconductor light emitting device of claim 4, wherein the first pad electrode is positioned across a central region in the upper portions of the respective first and second light emitting units to cover both the first light emitting unit and the second light emitting unit, and
the first horizontal connection is positioned at a distance from the first pad electrode, along the left and/or right edges in the upper portions of the respective first and second light emitting units.

7. The semiconductor light emitting device of claim 4, further comprising:
a first branched finger electrode formed in the horizontal direction on the second semiconductor layer of the first light emitting unit, and/or a second branched finger electrode formed in the horizontal direction on the first semiconductor layer of the second light emitting unit,
wherein the first branched finger electrode and/or the second branched finger electrode is arranged to be covered by the first pad electrode and the first upper electrode.

8. The semiconductor light emitting device of claim 4, further comprising:
a second connecting electrode for connecting the second light emitting unit and the third light emitting unit,
wherein the second connecting electrode includes a first-a lower connection, a second horizontal connection, and a second-a lower connection,
the second horizontal connection is positioned across the upper portions of the respective second and third light emitting units,
the first-a lower connection electrically connects one end of the second horizontal connection to the second semiconductor layer of the second light emitting unit,
the second-a lower connection electrically connects the other end of the second horizontal connection to the first semiconductor layer of the third light emitting unit, and
the second horizontal connection is formed on a layer at the same height as the first pad electrode, in an upper portion of the second light emitting unit that is not covered by the first pad electrode.
